(19) United States
(12) Patent Application Publication
(10) Pub. No.: US 2026/0101531 A1
(43) Pub. Date: Apr. 9, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Wei-Ting CHANG, Hsinchu (TW); Ching Yu CHEN, Hsinchu (TW); JIANG-HE XIE, Hsinchu (TW)

(73) Assignee: Taiwan Semiconductor Manufacturing Company, Ltd., Hsinchu (TW)

(21) Appl. No.: 18/905,488

(22) Filed: Oct. 3, 2024

(51) Int. Cl. H01L 29/778; H01L 29/20; H01L 29/36; H01L 29/66

(52) U.S. Cl. CPC H10D 30/475; H10D 30/015; H10D 62/60; H10D 62/8503

(57) ABSTRACT

A semiconductor structure and a manufacturing method thereof are provided. The semiconductor structure includes a nucleation layer, a strain relief layer, a P-doping GaN layer, a GaN channel layer and an AlGaN barrier layer. The strain relief layer is disposed on the nucleation layer. The strain relief layer has a plurality of modulated P-doping concentrations. The P-doping GaN layer is disposed on the strain relief layer. The GaN channel layer is disposed on the P-doping GaN layer. The AlGaN barrier layer is disposed on the GaN channel layer.

### BACKGROUND

The disclosure relates in general to a semiconductor structure and a manufacturing method thereof, and more particularly to a semiconductor structure having a channel layer and a manufacturing method thereof.

In a semiconductor structure having a channel layer, the device capacitance is an importance to well control the bulk leakage, the breakdown voltage (BV), and the trapping effect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor structure according to one embodiment of the present disclosure.

FIG. 2A shows a D-mode high electron mobility transistor (HEMT) according to one embodiment of the present disclosure.

FIG. 2B shows an E-mode HEMT according to one embodiment of the present disclosure.

FIG. 3A shows a strain relief layer according to one embodiment of the present disclosure.

FIG. 3B shows a strain relief layer according to another embodiment of the present disclosure.

FIG. 3C shows a strain relief layer according to another embodiment of the present disclosure.

FIG. 4 shows strain relief layers according to several embodiments of the present disclosure.

FIG. 5 shows the P-doping concentrations of the strain relief layers according to the embodiments described in the FIG. 4.

FIG. 6 shows strain relief layers according to several embodiments of the present disclosure.

FIG. 7 shows the P-doping concentrations of the strain relief layers according to the embodiments described in the FIG. 6.

FIG. 8 shows strain relief layers according to several embodiments of the present disclosure.

FIG. 9 shows the P-doping concentrations of the strain relief layers according to the embodiments described in the FIG. 8.

FIG. 10 shows strain relief layers according to several embodiments of the present disclosure.

FIG. 11 shows the P-doping concentrations of the strain relief layers according to the embodiments described in the FIG. 10.

FIG. 12 shows a flowchart of a manufacturing method of the D-mode HEMT including the semiconductor structure according to one embodiment of the present disclosure.

FIGS. 13A and 13B show a flowchart of a manufacturing method of the E-mode HEMT including the semiconductor structure according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

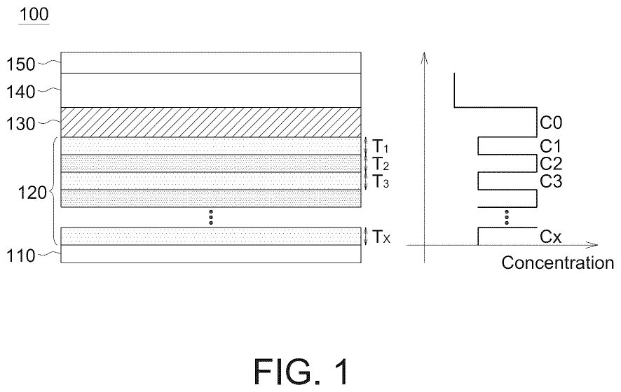

Please refer to FIG. 1, which shows a semiconductor structure 100 according to one embodiment of the present disclosure. The semiconductor 100 includes a nucleation layer 110, a strain relief layer 120, a P-doping GaN layer 130, a GaN channel layer 140 and an AlGaN barrier layer 150. The nucleation layer 110 is used to act as a buffer to reduce stress between a substrate and other layer. The material of the nucleation layer 110 is, for example, AlN.

The strain relief layer 120 is disposed on the nucleation layer 110, and used to relief the strain among the layers. The material of the strain relief layer 120 is, for example, AlGaN, GaN, AlN or the combination thereof. In one embodiment, the strain relief layer 120 has a plurality of modulated P-doping concentrations C1, C2, C3, . . . , Cx. The modulated P-doping concentrations C1, C2, C3, . . . , Cx are not all equal. For example, the modulated P-doping concentrations C1, C2, C3, . . . , Cx are staggered up and down. A ratio of two of the modulated P-doping concentrations C1, C2, C3, . . . , Cx is more than 2. For example, a ratio of the adjacent modulated P-doping concentrations C1, C2 is more than 2, a ratio of the adjacent modulated P-doping concentrations C2, C3 is more than 2, and so on. Each of the thicknesses T1, T2, T3, . . . , Tx corresponding the modulated P-doping concentrations C1, C2, C3, . . . , Cx is larger than 50 nm.

The P-doping GaN layer 130 is disposed on the strain relief layer 120. For example, the P-doping GaN layer 130 is a P-doping AlGaN layer and doped C or Fe.

The GaN channel layer 140 is disposed on the P-doping GaN layer 130. The GaN channel layer 140 is unintentionally doped GaN.

The AlGaN barrier layer 150 is disposed on the GaN channel layer 140.

In this embodiment, additional multi-modulated C, Fe, Mg or Mn doping in the strain relief layer 120 is used to compensate nature n-type conductive buffer. The strain relief layer 120 having the different modulated P-doping concentrations C1, C2, C3, . . . , Ck, uses modulated p-type doping buffer to increase the device capacitance to achieve lower bulk leakage, high breakdown voltage (BV), and further minimized buffer trapping effect. The different modulated P-doping concentrations C1, C2, C3, . . . , Ck could create more than one p-p^{-¿¿}, p-i or p-n junctions.

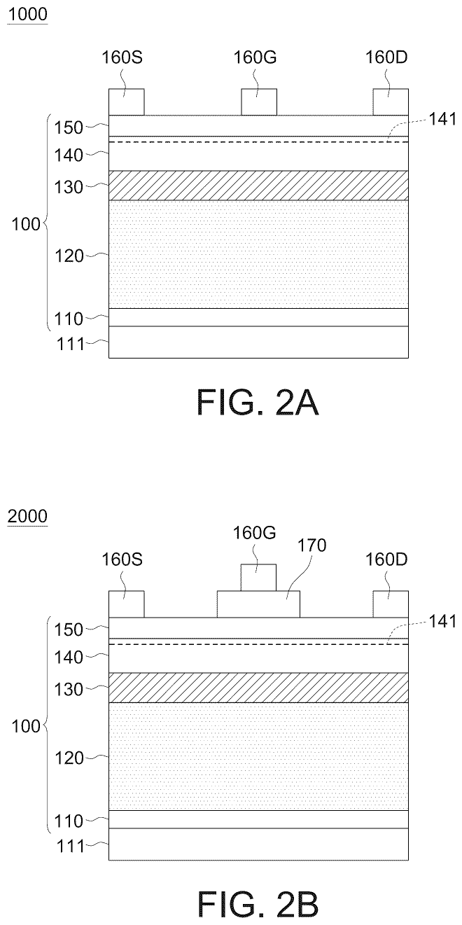

Please refer to FIGS. 2A and 2B. FIG. 2A shows a D-mode high electron mobility transistor (HEMT) 1000 according to one embodiment of the present disclosure. FIG. 2B shows an E-mode HEMT 2000 according to one embodiment of the present disclosure. The semiconductor structure 100 could be used in the D-mode HEMT 1000 or the E-mode HEMT 2000. The D-mode HEMT 1000 includes a substrate 111, the semiconductor structure 100, a gate 160G, a source 160S and a drain 160D. The E-mode HEMT 2000 includes the substrate 111, the semiconductor structure 100, the gate 160G, the source 160S, the drain 160D and the p-GaN layer 170. A GaN HEMT is designed with a unique aluminum gallium nitride (Al—GaN)/GaN heterojunction structure where two-dimensional electron gas (2DEG) 141 is formed. The 2DEG 141 allows large bidirectional current and yields extremely low on resistance. The GaN HEMTs are currently divided into three types: depletion mode (D-mode), enhancement mode (E-mode), and cascode devices. The D-mode HEMT 1000, as shown in the FIG. 2A, is naturally on because of the 2DEG 141 and can be turned off with negative gate-source voltage. The E-mode HEMT 2000, as shown in the FIG. 2B, is normally off because the 2DEG 141 has been depleted by an additional P-doped layer of GaN or AlGaN on the gate 160G, and it can be turned on with appropriate gate-source voltage.

Expect D-mode HEMT 1000 and E-mode HEMT 2000, the semiconductor structure 100 could be used in all GaN-based device, such as LEDs/laser, power devices, RF devise, photonics device, high-frequency communications device, and high-power conversion device.

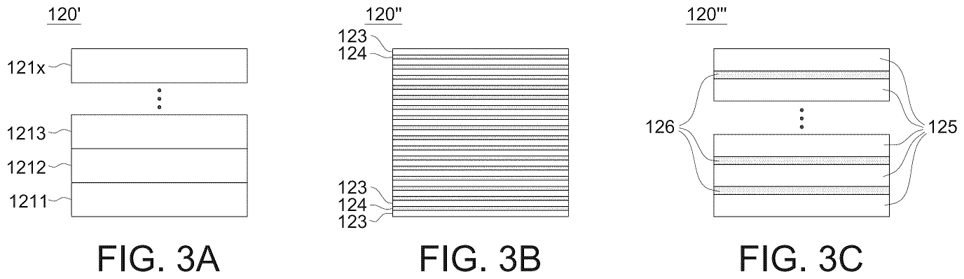

Please refer to FIG. 3A, which shows a strain relief layer 120′ according to one embodiment of the present disclosure. The strain relief layer 120 could be relied by the strain relief layer 120′ of the FIG. 3A. The strain relief layer 120′ includes a plurality of AlGaN layers 1211, 1212, 1213, . . . , 121x whose Al compositions are reduced step by step. The modulated P-doping concentrations C1, C2, C3, . . . , Ck are not directly related with the AlGaN layers 1211, 1212, 1213, . . . , 121x.

Please refer to FIG. 3B, which shows a strain relief layer 120″ according to another embodiment of the present disclosure. The strain relief layer 120 could be relied by the strain relief layer 120″ of the FIG. 3B. The strain relief layer 120″ includes a plurality of Al(Ga)N layers 123 and a plurality of GaN layers 124 which are stacked alternately. The modulated P-doping concentrations C1, C2, C3, . . . , Ck are not directly related with the Al(Ga)N layers 123 and the GaN layers 124.

Please refer to FIG. 3C, which shows a strain relief layer 120″′ according to another embodiment of the present disclosure. The strain relief layer 120 could be relied by the strain relief layer 120″′ of the FIG. 3C. The strain relief layer 120″′ includes a (Al)GaN layer 125 with a plurality of Al(Ga)N interlayers 126. The modulated P-doping concentrations C1, C2, C3, . . . , Ck are not directly related with the (Al)GaN layer 125 with the Al(Ga)N interlayers 126.

The modulated P-doping concentrations C1, C2, C3, . . . , Ck could result the p-p^{-¿¿}, p-i, or p-n junctions in varied ways. The following shows the different examples to implement the modulated P-doping concentrations C1, C2, C3, . . . , Ck.

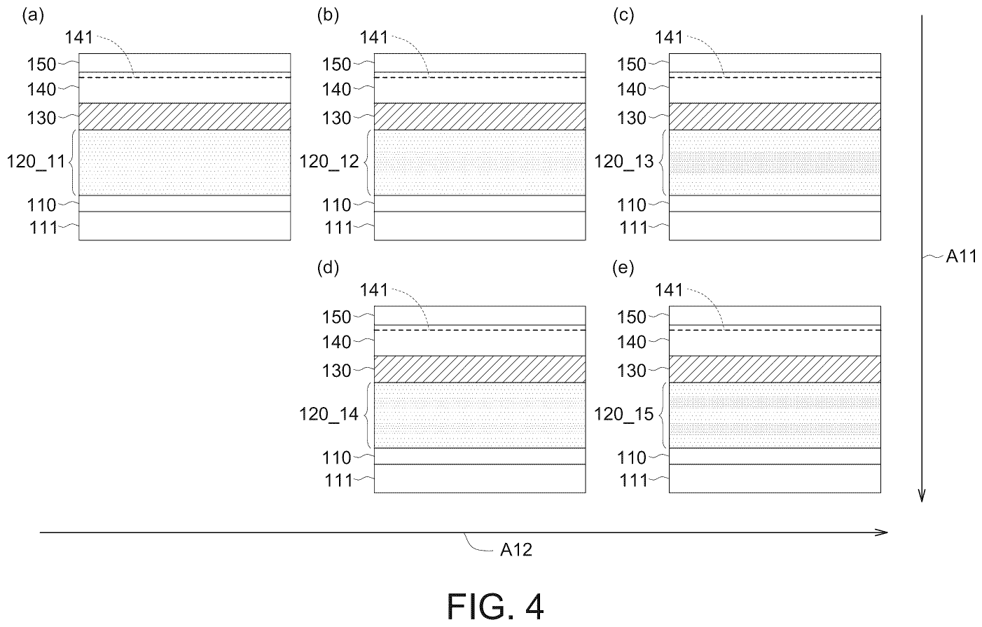

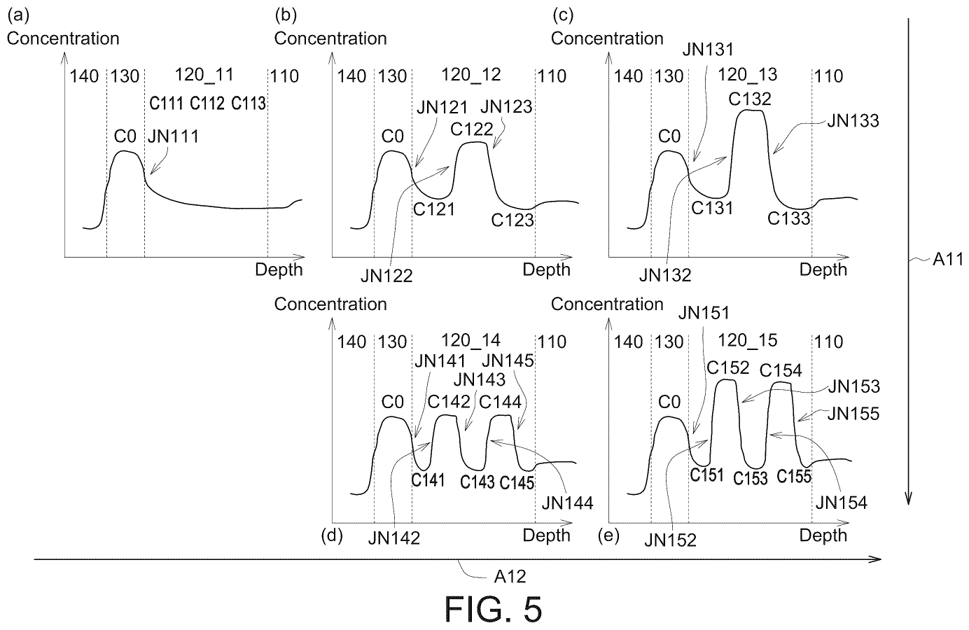

Please refer to FIGS. 4 and 5. FIG. 4 shows strain relief layers 120_11 to 120_15 according to several embodiments of the present disclosure, and FIG. 5 shows the P-doping concentrations of the strain relief layers according to the embodiments described in the FIG. 4. As shown in the drawing (a) of the FIG. 4, the strain relief layer 120_11 is not additionally doped the P-type dopants; as shown in the drawing (a) of the FIG. 5, the P-doping concentration C0 is high and the P-doping concentrations C111, C112, C113 are kept at low. A (p-p^{-¿¿}, p-i, or p-n) junction JN111 is generated between the P-doping concentration C0 and the P-doping concentration C111.

As shown in the drawing (b) of the FIG. 4, the strain relief layer 120_12 is additionally doped the P-type dopants; as shown in the drawing (b) of the FIG. 5, the P-doping concentration C122 is higher than the P-doping concentrations C121, C123. A (p-p^{-¿¿}, p-i, or p-n) junction JN121 is generated between the P-doping concentration C0 and the P-doping concentration C121, a (p-p^{-¿¿}, p-i, or p-n) junction JN122 is generated between the P-doping concentration C121 and the P-doping concentration C122, and a (p-p^{-¿¿}, p-i, or p-n) junction JN123 is generated between the P-doping concentration C122 and the P-doping concentration C123. Compared to the strain relief layer 120_11, the junctions JN122, JN123 of the strain relief layer 120_12 could result junction capacitances to reduce the bulk leakage and increase the breakdown voltage (BV).

As shown in the drawing (c) of the FIG. 4, the strain relief layer 120_13 is additionally doped the P-type dopants; as shown in the drawing (c) of the FIG. 5, the P-doping concentration C132 is higher than the P-doping concentrations C131, C133. A (p-p^{-¿¿}, p-i, or p-n) junction JN131 is generated between the P-doping concentration C0 and the P-doping concentration C131, a (p-p^{-¿¿}, p-i, or p-n) junction JN132 is generated between the P-doping concentration C131 and the P-doping concentration C132 and another (p-p^{-¿¿}, p-i, or p-n) junction JN132 is generated between the P-doping concentration C132 and the P-doping concentration C133. Compared to the strain relief layer 120_12, the higher P-doping concentration C132 of the strain relief layer 120_13 could result higher junction capacitances; therefore, the bulk leakage is further reduced and the breakdown voltage (BV) is further increased.

As shown in the drawing (d) of the FIG. 4, the strain relief layer 120_14 is additionally doped the P-type dopants; as shown in the drawing (d) of the FIG. 5, the P-doping concentrations C142, C144 are higher than the P-doping concentrations C141, C143, C145. A (p-p^{-¿¿}, p-i, or p-n) junction JN141 is generated between the P-doping concentration C0 and the P-doping concentration C141, another (p-p^{-¿¿}, p-i, or p-n) junction JN142 is generated between the P-doping concentration C141 and the P-doping concentration C142, another (p-p^{-¿¿}, p-i, or p-n) junction JN143 is generated between the P-doping concentration C142 and the P-doping concentration C143, another (p-p^{-¿¿}, p-i, or p-n) junction JN144 is generated between the P-doping concentration C143 and the P-doping concentration C144, and another (p-p^{-¿¿}, p-i, or p-n) junction JN145 is generated between the P-doping concentration C144 and the P-doping concentration C145. Compared to the strain relief layer 120_12, more junctions JM141, JN142, JN143, JN144, JN145 of the strain relief layer 120_14 could result more junction capacitances to reduce the bulk leakage and increase the breakdown voltage (BV).

As shown in the drawing (e) of the FIG. 4, the strain relief layer 120_15 is additionally doped the P-type dopants; as shown in the drawing (e) of the FIG. 5, the P-doping concentrations C152, C152 are higher than the P-doping concentrations C151, C153, C155. A (p-p^{-¿¿}, p-i, or p-n) junction JN151 is generated between the P-doping concentration C0 and the P-doping concentration C151, another (p-p^{-¿¿}, p-i, or p-n) junction JN152 is generated between the P-doping concentration C151 and the P-doping concentration C152, another (p-p^{-¿¿}, p-i, or p-n) junction JN153 is generated between the P-doping concentration C152 and the P-doping concentration C153, another (p-p^{-¿¿}, p-i, or p-n) junction JN154 is generated between the P-doping concentration C153 and the P-doping concentration C154, and another (p-p^{-¿¿}, p-i, or p-n) junction JN153 is generated between the P-doping concentration C154 and the P-doping concentration C155. Compared to the strain relief layer 120_14, the higher P-doping concentrations C152, C154 of the strain relief layer 120_15 could result higher junction capacitances; therefore, the bulk leakage is further reduced and the breakdown voltage (BV) is further increased.

As shown in the FIGS. 4 and 5, an arrow A11 shows that the greater the number of the different P-doping concentrations, the lower the bulk leakage will be and the higher the breakdown voltage (BV) will be; an arrow A12 shows that the higher the high P-doping concentration, the lower the bulk leakage will be and the higher the breakdown voltage (BV) will be.

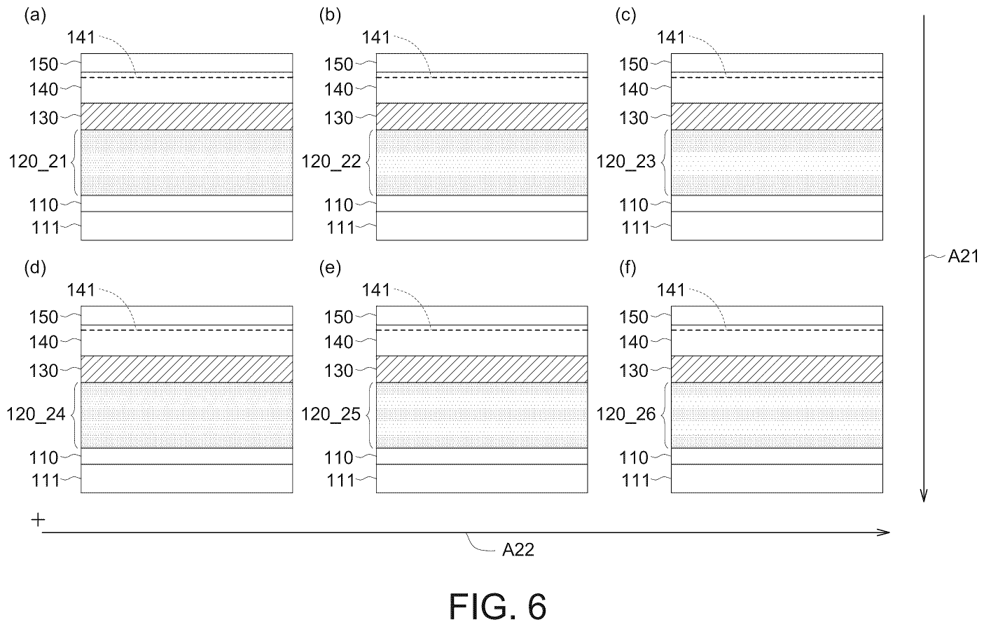

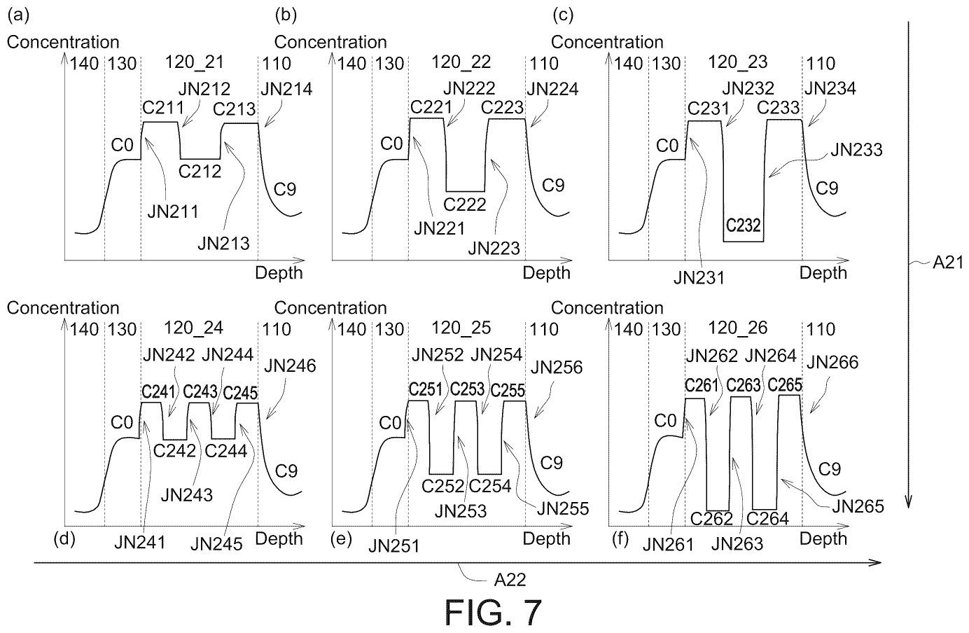

Please refer to FIGS. 6 and 7. FIG. 6 shows strain relief layers 120_21 to 120_26 according to several embodiments of the present disclosure, and FIG. 7 shows the P-doping concentrations of the strain relief layers according to the embodiments described in the FIG. 6. As shown in the drawing (a) of the FIG. 6, the strain relief layer 120_21 is additionally doped the P-type dopants; as shown in the drawing (a) of the FIG. 7, the P-doping concentrations C211, C213 are higher than the P-doping concentration C212, and the P-doping concentration C212 is substantially equal to the P-doping concentration C0. A (p-p^{-¿¿}, p-i, or p-n) junction JN211 is generated between the P-doping concentration C0 and the P-doping concentration C211, another (p-p^{-¿¿}, p-i, or p-n) junction JN212 is generated between the P-doping concentration C211 and the P-doping concentration C212, another (p-p^{-¿¿}, p-i, or p-n) junction JN213 is generated between the P-doping concentration C212 and the P-doping concentration C213, and another (p-p^{-¿¿}, p-i, or p-n) junction JN214 is generated between the P-doping concentration C213 and the P-doping concentration C9.

As shown in the drawing (b) of the FIG. 6, the strain relief layer 120_22 is additionally doped the P-type dopants; as shown in the drawing (b) of the FIG. 7, the P-doping concentrations C221, C223 are higher than the P-doping concentration C222. A (p-p^{-¿¿}, p-i, or p-n) junction JN221 is generated between the P-doping concentration C0 and the P-doping concentration C221, another (p-p^{-¿¿}, p-i, or p-n) junction JN222 is generated between the P-doping concentration C221 and the P-doping concentration C222, another (p-p^{-¿¿}, p-i, or p-n) junction JN223 is generated between the P-doping concentration C222 and the P-doping concentration C223, and another (p-p^{-¿¿}, p-i, or p-n) junction JN224 is generated between the P-doping concentration C223 and the P-doping concentration C9. Compared to the strain relief layer 120_21, the lower P-doping concentration C222 could result higher junction capacitances; therefore, the bulk leakage is further reduced and the breakdown voltage (BV) is further increased.

As shown in the drawing (c) of the FIG. 6, the strain relief layer 120_23 is additionally doped the P-type dopants; as shown in the drawing (c) of the FIG. 7, the P-doping concentrations C231, C233 are higher than the P-doping concentration C232. A (p-p^{-¿¿}, p-i, or p-n) junction JN231 is generated between the P-doping concentration C0 and the P-doping concentration C231, another (p-p^{-¿¿}, p-i, or p-n) junction JN232 is generated between the P-doping concentration C231 and the P-doping concentration C232, another (p-p^{-¿¿}, p-i, or p-n) junction JN233 is generated between the P-doping concentration C232 and the P-doping concentration C233, and another (p-p^{-¿¿}, p-i, or p-n) junction JN234 is generated between the P-doping concentration C233 and the P-doping concentration C9. Compared to the strain relief layer 120_22, the lower P-doping concentration C232 of the strain relief layer 120_23 could result higher junction capacitances; therefore, the bulk leakage is further reduced and the breakdown voltage (BV) is further increased.

As shown in the drawing (d) of the FIG. 6, the strain relief layer 120_24 is additionally doped the P-type dopants; as shown in the drawing (d) of the FIG. 7, the P-doping concentrations C241, C243, C245 are higher than the P-doping concentrations C242, C244. A (p-p^{-¿¿}, p-i, or p-n) junction JN241 is generated between the P-doping concentration C0 and the P-doping concentration C241, another (p-p^{-¿¿}, p-i, or p-n) junction JN242 is generated between the P-doping concentration C241 and the P-doping concentration C242, another (p-p^{-¿¿}, p-i, or p-n) junction JN243 is generated between the P-doping concentration C242 and the P-doping concentration C243, another (p-p^{-¿¿}, p-i, or p-n) junction JN244 is generated between the P-doping concentration C243 and the P-doping concentration C244, another (p-p^{-¿¿}, p-i, or p-n) junction JN245 is generated between the P-doping concentration C244 and the P-doping concentration C245, and another (p-p^{-¿¿}, p-i, or p-n) junction JN246 is generated between the P-doping concentration C245 and the P-doping concentration C9. Compared to the strain relief layer 120_21, more junctions JN241, JN242, JN243, JN244, JN245, JN246 of the strain relief layer 120_24 could result more junction capacitances to reduce the bulk leakage and increase the breakdown voltage (BV).

As shown in the drawing (e) of the FIG. 6, the strain relief layer 120_25 is additionally doped the P-type dopants; as shown in the drawing (e) of the FIG. 7, the P-doping concentrations C251, C253, C255 are higher than the P-doping concentrations C252, C254. A (p-p^{-¿¿}, p-i, or p-n) junction JN251 is generated between the P-doping concentration C0 and the P-doping concentration C251, another (p-p^{-¿¿}, p-i, or p-n) junction JN252 is generated between the P-doping concentration C251 and the P-doping concentration C252, another (p-p^{-¿¿}, p-i, or p-n) junction JN253 is generated between the P-doping concentration C252 and the P-doping concentration C253, another (p-p^{-¿¿}, p-i, or p-n) junction JN254 is generated between the P-doping concentration C253 and the P-doping concentration C254, another (p-p^{-¿¿}, p-i, or p-n) junction JN255 is generated between the P-doping concentration C254 and the P-doping concentration C255, and another (p-p^{-¿¿}, p-i, or p-n) junction JN256 is generated between the P-doping concentration C255 and the P-doping concentration C9. Compared to the strain relief layer 120_24, the lower P-doping concentrations C252, C254 of the strain relief layer 120_25 could result higher junction capacitances; therefore, the bulk leakage is further reduced and the breakdown voltage (BV) is further increased.

As shown in the drawing (f) of the FIG. 6, the strain relief layer 120_26 is additionally doped the P-type dopants; as shown in the drawing (f) of the FIG. 7, the P-doping concentrations C261, C263, C265 are higher than the P-doping concentrations C262, C264. A (p-p^{-¿¿}, p-i, or p-n) junction JN261 is generated between the P-doping concentration C0 and the P-doping concentration C261, another (p-p^{-¿¿}, p-i, or p-n) junction JN262 is generated between the P-doping concentration C261 and the P-doping concentration C262, another (p-p^{-¿¿}, p-i, or p-n) junction JN263 is generated between the P-doping concentration C262 and the P-doping concentration C263, another (p-p^{-¿¿}, p-i, or p-n) junction JN264 is generated between the P-doping concentration C263 and the P-doping concentration C264, another (p-p^{-¿¿}, p-i, or p-n) junction JN265 is generated between the P-doping concentration C264 and the P-doping concentration C265, and another (p-p^{-¿¿}, p-i, or p-n) junction JN266 is generated between the P-doping concentration C265 and the P-doping concentration C9. Compared to the strain relief layer 120_25, the lower P-doping concentrations C262, C264 of the strain relief layer 120_26 could result higher junction capacitances; therefore, the bulk leakage is further reduced and the breakdown voltage (BV) is further increased.

As shown in the FIGS. 6 and 7, an arrow A21 shows that the greater the number of the different P-doping concentrations, the lower the bulk leakage will be and the higher the breakdown voltage (BV) will be; an arrow A22 shows that the lower the low P-doping concentration, the lower the bulk leakage will be and the higher the breakdown voltage (BV) will be.

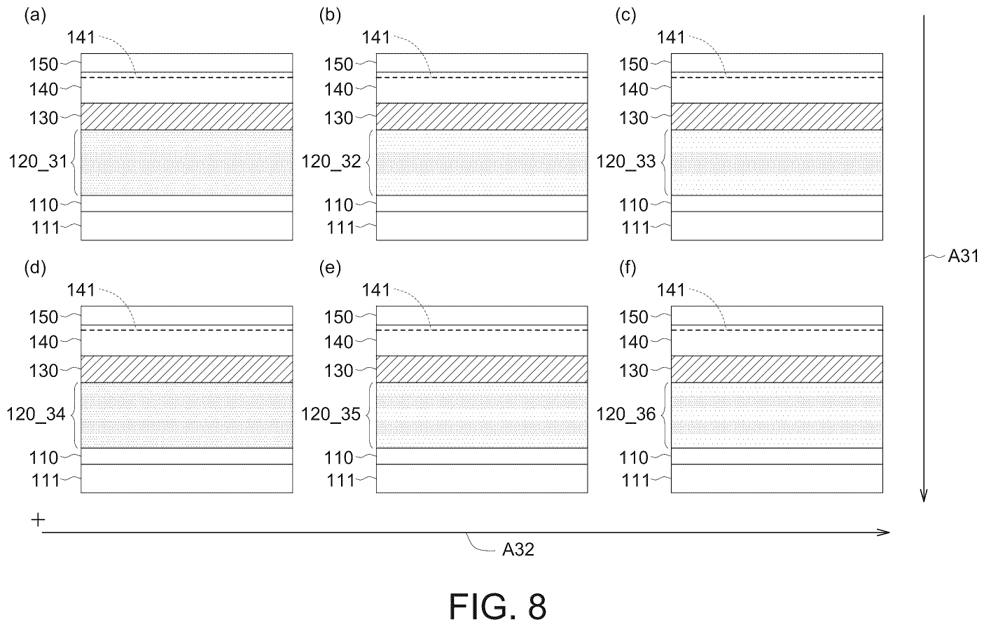

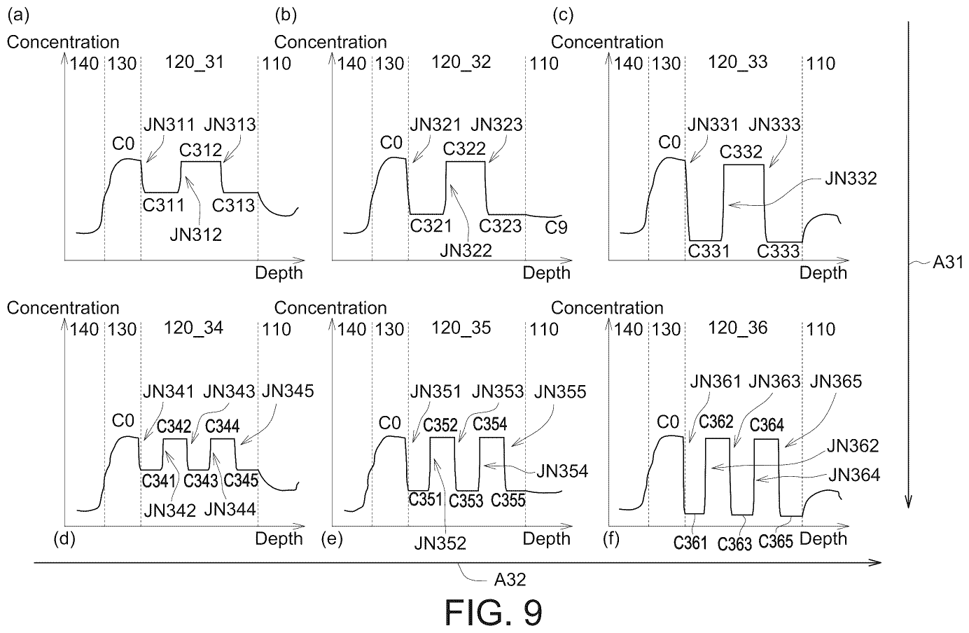

Please refer to FIGS. 8 and 9. FIG. 8 shows strain relief layers 120_31 to 120_36 according to several embodiments of the present disclosure, and FIG. 9 shows the P-doping concentrations of the strain relief layers according to the embodiments described in the FIG. 8. As shown in the drawing (a) of the FIG. 8, the strain relief layer 120_31 is additionally doped the P-type dopants; as shown in the drawing (a) of the FIG. 9, the P-doping concentration C312 is higher than the P-doping concentrations C311, C313, and the P-doping concentrations C311, C313 are substantially equal to the P-doping concentration C0. A (p-p^{-¿¿}, p-i, or p-n) junction JN311 is generated between the P-doping concentration C0 and the P-doping concentration C311, another (p-p^{-¿¿}, p-i, or p-n) junction JN312 is generated between the P-doping concentration C311 and the P-doping concentration C312, and another (p-p^{-¿¿}, p-i, or p-n) junction JN313 is generated between the P-doping concentration C312 and the P-doping concentration C313.

As shown in the drawing (b) of the FIG. 8, the strain relief layer 120_32 is additionally doped the P-type dopants; as shown in the drawing (b) of the FIG. 9, the P-doping concentration C322 is higher than the P-doping concentrations C321, C323 and the P-doping concentration C322 is substantially equal to the P-doping concentration C0. A (p-p^{-¿¿}, p-i, or p-n) junction JN321 is generated between the P-doping concentration C0 and the P-doping concentration C321, another (p-p^{-¿¿}, p-i, or p-n) junction JN322 is generated between the P-doping concentration C321 and the P-doping concentration C322, and another (p-p^{-¿¿}, p-i, or p-n) junction JN322 is generated between the P-doping concentration C322 and the P-doping concentration C323. Compared to the strain relief layer 120_31, the lower P-doping concentrations C321, C323 could result higher junction capacitance; therefore, the bulk leakage is further reduced and the breakdown voltage (BV) is further increased.

As shown in the drawing (c) of the FIG. 8, the strain relief layer 120_33 is additionally doped the P-type dopants; as shown in the drawing (c) of the FIG. 9, the P-doping concentration C332 is higher than the P-doping concentrations C331, C333, and the P-doping concentration C332 is substantially equal to the P-doping concentration C0. A (p-p^{-¿¿}, p-i, or p-n) junction JN331 is generated between the P-doping concentration C0 and the P-doping concentration C331, another (p-p^{-¿¿}, p-i, or p-n) junction JN332 is generated between the P-doping concentration C331 and the P-doping concentration C332, and another (p-p^{-¿¿}, p-i, or p-n) junction JN332 is generated between the P-doping concentration C332 and the P-doping concentration C333. Compared to the strain relief layer 120_32, the lower P-doping concentrations C331, C333 could result higher junction capacitance; therefore, the bulk leakage is further reduced and the breakdown voltage (BV) is further increased.

As shown in the drawing (d) of the FIG. 8, the strain relief layer 120_34 is additionally doped the P-type dopants; as shown in the drawing (d) of the FIG. 9, the P-doping concentrations C342, C344 are higher than the P-doping concentrations C341, C343, C345, and the P-doping concentrations C342, C344 are substantially equal to the P-doping concentration C0. A (p-p^{-¿¿}, p-i, or p-n) junction JN341 is generated between the P-doping concentration C0 and the P-doping concentration C341, another (p-p^{-¿¿}, p-i, or p-n) junction JN342 is generated between the P-doping concentration C341 and the P-doping concentration C342, another (p-p^{-¿¿}, p-i, or p-n) junction JN343 is generated between the P-doping concentration C342 and the P-doping concentration C343, another (p-p^{-¿¿}, p-i, or p-n) junction JN344 is generated between the P-doping concentration C343 and the P-doping concentration C344, and another (p-p^{-¿¿}, p-i, or p-n) junction JN345 is generated between the P-doping concentration C344 and the P-doping concentration C345. Compared to the strain relief layer 120_31, more junctions JN341, JN342, JN343, JN344, JN345 of the strain relief layer 120_34 could result more junction capacitances to reduce the bulk leakage and increase the breakdown voltage (BV).

As shown in the drawing (e) of the FIG. 8, the strain relief layer 120_35 is additionally doped the P-type dopants; as shown in the drawing (e) of the FIG. 9, the P-doping concentrations C352, C354 are higher than the P-doping concentrations C351, C353, C355 and the P-doping concentrations C352, C354 are substantially equal to the P-doping concentration C0. A (p-p^{-¿¿}, p-i, or p-n) junction JN351 is generated between the P-doping concentration C0 and the P-doping concentration C351, another (p-p^{-¿¿}, p-i, or p-n) junction JN352 is generated between the P-doping concentration C351 and the P-doping concentration C352, another (p-p^{-¿¿}, p-i, or p-n) junction JN353 is generated between the P-doping concentration C352 and the P-doping concentration C353, another (p-p^{-¿¿}, p-i, or p-n) junction JN354 is generated between the P-doping concentration C353 and the P-doping concentration C354, and another (p-p^{-¿¿}, p-i, or p-n) junction JN355 is generated between the P-doping concentration C354 and the P-doping concentration C355. Compared to the strain relief layer 120_34, the lower P-doping concentrations C351, C353, C355 of the strain relief layer 120_35 could result higher junction capacitances; therefore, the bulk leakage is further reduced and the breakdown voltage (BV) is further increased.

As shown in the drawing (f) of the FIG. 8, the strain relief layer 120_36 is additionally doped the P-type dopants; as shown in the drawing (f) of the FIG. 9, the P-doping concentrations C362, C364 are higher than the P-doping concentrations C361, C363, C365, and the P-doping concentrations C362, C364 are substantially equal to the P-doping concentration C0. A (p-p^{-¿¿}, p-i, or p-n) junction JN361 is generated between the P-doping concentration C0 and the P-doping concentration C361, another (p-p^{-¿¿}, p-i, or p-n) junction JN362 is generated between the P-doping concentration C361 and the P-doping concentration C362, another (p-p^{-¿¿}, p-i, or p-n) junction JN363 is generated between the P-doping concentration C362 and the P-doping concentration C363, another (p-p^{-¿¿}, p-i, or p-n) junction JN364 is generated between the P-doping concentration C363 and the P-doping concentration C364, and another (p-p^{-¿¿}, p-i, or p-n) junction JN365 is generated between the P-doping concentration C364 and the P-doping concentration C365. Compared to the strain relief layer 120_35, the lower P-doping concentrations C361, C363, C365 of the strain relief layer 120_36 could result higher junction capacitances; therefore, the bulk leakage is further reduced and the breakdown voltage (BV) is further increased.

As shown in the FIGS. 8 and 9, an arrow A31 shows that the greater the number of the different P-doping concentrations, the lower the bulk leakage will be and the higher the breakdown voltage (BV) will be; an arrow A32 shows that the lower the low P-doping concentration, the lower the bulk leakage will be and the higher the breakdown voltage (BV) will be.

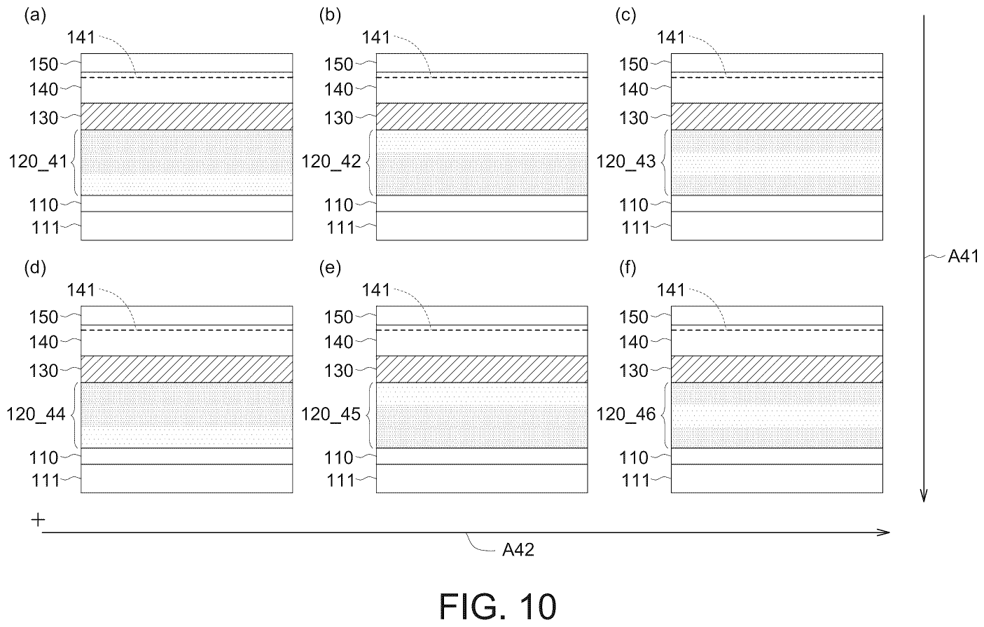

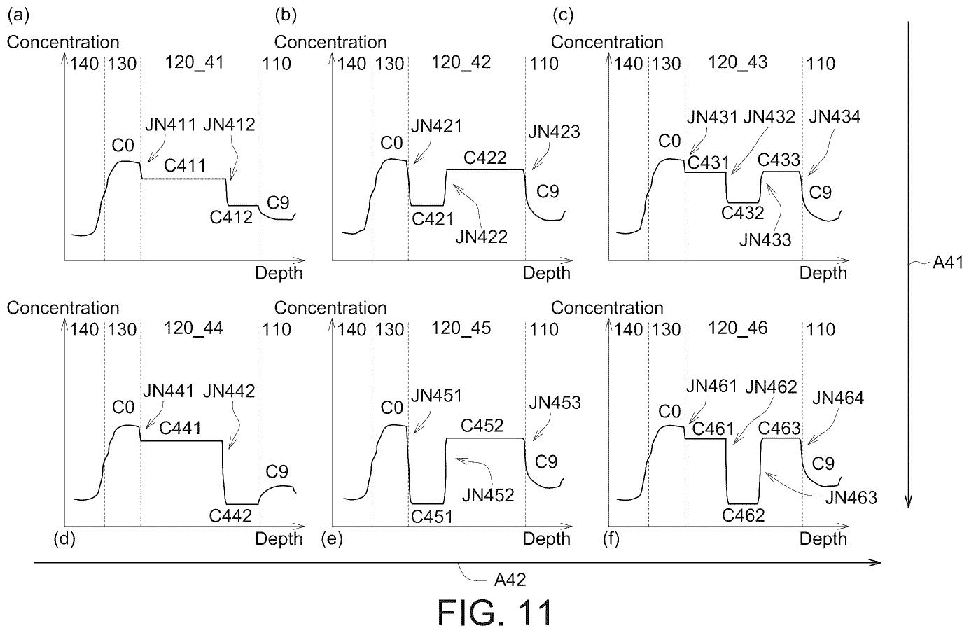

Please refer to FIGS. 10 and 11. FIG. 10 shows strain relief layers 120_41 to 120_46 according to several embodiments of the present disclosure, and FIG. 11 shows the P-doping concentrations of the strain relief layers according to the embodiments described in the FIG. 10. As shown in the drawing (a) of the FIG. 10, the strain relief layer 120_41 is additionally doped the P-type dopants; as shown in the drawing (a) of the FIG. 11, the P-doping concentrations C411, C412 are lower than the P-doping concentration C0, and the P-doping concentration C411 is higher than the P-doping concentration C412. A (p-p^{-¿¿}, p-i, or p-n) junction JN411 is generated between the P-doping concentration C0 and the P-doping concentration C411, and another (p-p^{-¿¿}, p-i, or p-n) junction JN412 is generated between the P-doping concentration C411 and the P-doping concentration C412.

As shown in the drawing (b) of the FIG. 10, the strain relief layer 120_42 is additionally doped the P-type dopants; as shown in the drawing (b) of the FIG. 11, the P-doping concentrations C421, C422 are lower than the P-doping concentration C0, and the P-doping concentration C422 is higher than the P-doping concentration C421. A (p-p^{-¿¿}, p-i, or p-n) junction JN421 is generated between the P-doping concentration C0 and the P-doping concentration C421, another (p-p^{-¿¿}, p-i, or p-n) junction JN422 is generated between the P-doping concentration C421 and the P-doping concentration C422, and another (p-p^{-¿¿}, p-i, or p-n) junction JN423 is generated between the P-doping concentration C422 and the P-doping concentration C9. Compared to the strain relief layer 120_31, the more up/down changes of the P-doping concentrations C421, C422 could result higher junction capacitance; therefore, the bulk leakage is further reduced and the breakdown voltage (BV) is further increased.

As shown in the drawing (c) of the FIG. 10, the strain relief layer 120_43 is additionally doped the P-type dopants; as shown in the drawing (c) of the FIG. 11, the P-doping concentrations C431, C432, C433 are lower than the P-doping concentration C0, and the P-doping concentrations C431, C433 are higher than the P-doping concentration C432. A (p-p^{-¿¿}, p-i, or p-n) junction JN431 is generated between the P-doping concentration C0 and the P-doping concentration C431, another (p-p^{-¿¿}, p-i, or p-n) junction JN432 is generated between the P-doping concentration C431 and the P-doping concentration C432, another (p-p^{-¿¿}, p-i, or p-n) junction JN433 is generated between the P-doping concentration C432 and the P-doping concentration C433, and another (p-p^{-¿¿}, p-i, or p-n) junction JN434 is generated between the P-doping concentration C433 and the P-doping concentration C9. Compared to the strain relief layer 120_32, the more up/down changes of the P-doping concentrations C431, C432, C433 could result higher junction capacitance; therefore, the bulk leakage is further reduced and the breakdown voltage (BV) is further increased.

As shown in the drawing (d) of the FIG. 10, the strain relief layer 120_44 is additionally doped the P-type dopants; as shown in the drawing (d) of the FIG. 11, the P-doping concentrations C441, C442 are lower than the P-doping concentration C0, and the P-doping concentration C441 is higher that the P-doping concentration C442. A (p-p^{-¿¿}, p-i, or p-n) junction JN441 is generated between the P-doping concentration C0 and the P-doping concentration C441, and another (p-p^{-¿¿}, p-i, or p-n) junction JN442 is generated between the P-doping concentration C441 and the P-doping concentration C442. Compared to the strain relief layer 120_41, the lower P-doping concentrations C442 could result higher junction capacitance; therefore, the bulk leakage is further reduced and the breakdown voltage (BV) is further increased.

As shown in the drawing (e) of the FIG. 10, the strain relief layer 120_45 is additionally doped the P-type dopants; as shown in the drawing (e) of the FIG. 11, the P-doping concentrations C451, C452 are lower than the P-doping concentration C0, and the P-doping concentration C452 is higher than the P-doping concentration C451. A (p-p^{-¿¿}, p-i, or p-n) junction JN451 is generated between the P-doping concentration C0 and the P-doping concentration C451, another (p-p^{-¿¿}, p-i, or p-n) junction JN452 is generated between the P-doping concentration C451 and the P-doping concentration C452, and another (p-p^{-¿¿}, p-i, or p-n) junction JN453 is generated between the P-doping concentration C452 and the P-doping concentration C9. Compared to the strain relief layer 120_44, the more up/down changes of the P-doping concentrations C451, C452 could result higher junction capacitance; therefore, the bulk leakage is further reduced and the breakdown voltage (BV) is further increased.

As shown in the drawing (f) of the FIG. 10, the strain relief layer 120_46 is additionally doped the P-type dopants; as shown in the drawing (f) of the FIG. 11, the P-doping concentrations C461, C462, C463 are lower than the P-doping concentration C0, and the P-doping concentrations C461, C463 are higher than the P-doping concentration C462. A (p-p^{-¿¿}, p-i, or p-n) junction JN461 is generated between the P-doping concentration C0 and the P-doping concentration C461, another (p-p^{-¿¿}, p-i, or p-n) junction JN462 is generated between the P-doping concentration C461 and the P-doping concentration C462, another (p-p^{-¿¿}, p-i, or p-n) junction JN463 is generated between the P-doping concentration C462 and the P-doping concentration C463, and another (p-p^{-¿¿}, p-i, or p-n) junction JN464 is generated between the P-doping concentration C463 and the P-doping concentration C9. Compared to the strain relief layer 120_45, the more up/down changes of the P-doping concentrations C461, C462, C463 could result higher junction capacitance; therefore, the bulk leakage is further reduced and the breakdown voltage (BV) is further increased.

As shown in the FIGS. 10 and 11, an arrow A41 shows that the lower the low P-doping concentration, the lower the bulk leakage will be and the higher the breakdown voltage (BV) will be; an arrow A42 shows that the more up/down changes of the P-doping concentrations, the lower the bulk leakage will be and the higher the breakdown voltage (BV) will be.

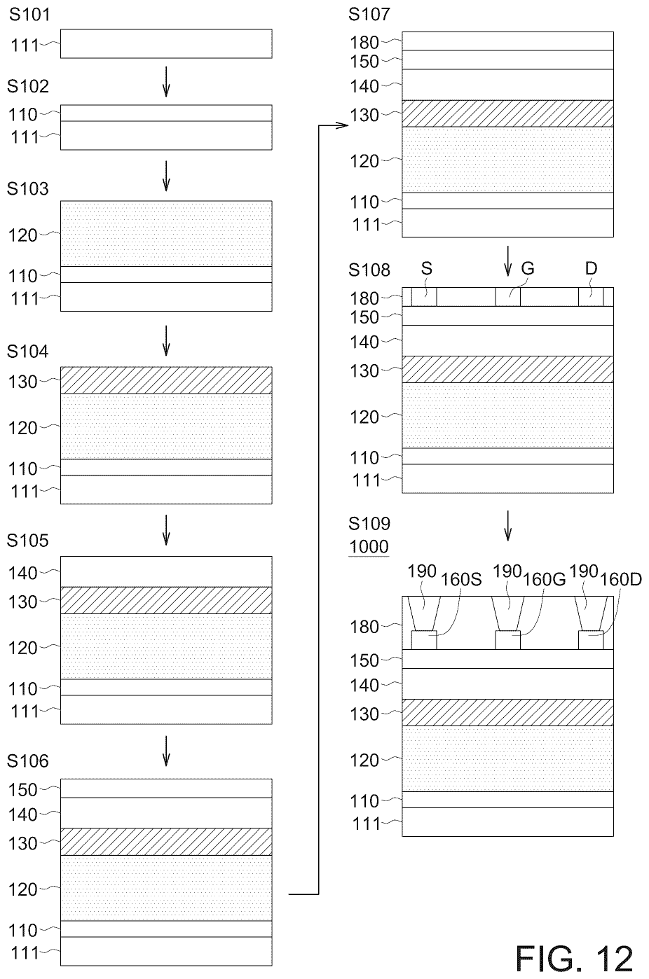

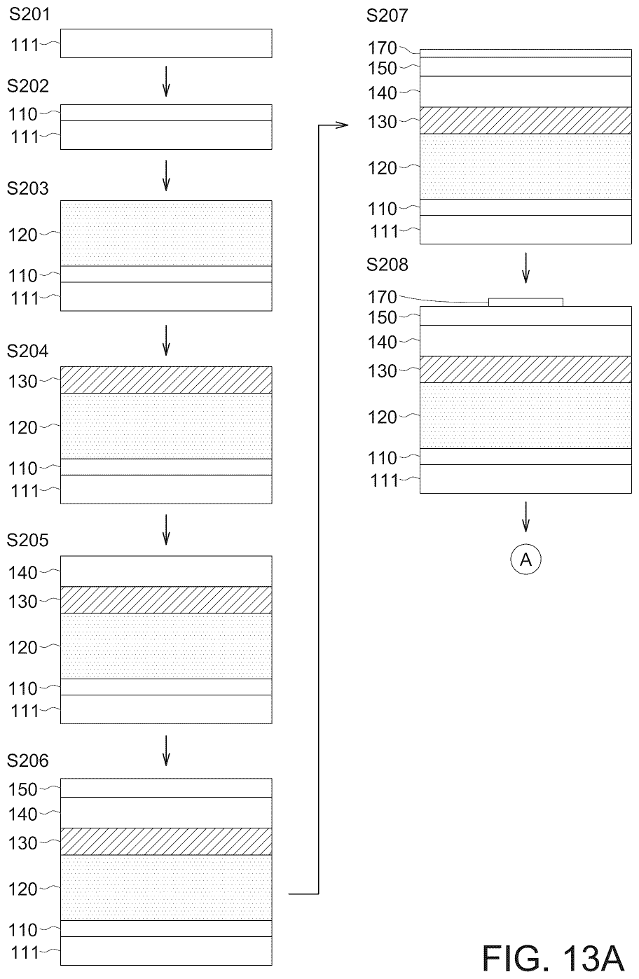

Please refer to FIG. 12, which shows a flowchart of a manufacturing method of the D-mode HEMT 1000 including the semiconductor structure 100 according to one embodiment of the present disclosure. The manufacturing method of the D-mode HEMT 1000 includes steps S101 to S109.

At the step S101, the substrate 111 is provided. For example, the material of the substrate 111 could be silicon (e.g. Si (111), Si (110) . . . ), sapphire (Al2O3), SiC, GaN, AlN, SOI (silicon-on-insulator), SIS (semi-insulated silicon). The substrate 111 could be a P-type substrate.

Then, at the step S102, the nucleation layer 110 is formed on the substrate 111. The material of the nucleation layer 110 is, for example, AlN.

Next, at the step S103, the strain relief layer 120 is formed on the nucleation layer 110. The material of the strain relief layer 120 is, for example, AlGaN, GaN, AlN or the combination thereof. The strain relief layer 120 is doped P-type dopants, such as C, Fe, Mg, Mn, to have the modulated P-doping concentrations C1, C2, C3, . . . , Cx. The strain relief layer 120 could be formed via Metal-organic Chemical Vapor Deposition (MOCVD), Metal-organic Vapor-Phase Epitaxy (MOVPE), Organometallic Vapor-Phase Epitaxy (OMVPE), or Organometallic Chemical Vapor Deposition (OMCVD).

In one embodiment for the step S103 of forming the strain relief layer 120, pressure, growth rate, temperature or content of precursor is controlled to intrinsically dope the P-type dopants.

In another embodiment for the step S103 of forming the strain relief layer 120, a source with the P-type dopants is injected into chamber to extrinsically dope the P-type dopants. For example, carbon source may include CH4, C2H4, C3H8, C6H12, and/or CBr4; ion source may include Cp2Fe, and/or FeCl2; others p-doping source may include Mn and/or Mg. Those sources are controlled by source MFC flow.

In another embodiment for the step S103 of forming the strain relief layer 120, the P-type dopants are implanted into the strain relief layer. For example, P-type source for implanting includes Fe and/or Mg.

Then, at the step S104, the P-doping GaN layer 130 is formed on the strain relief layer 120. For example, the P-doping GaN layer 130 is a P-doping AlGaN layer and doped C or Fe.

Afterwards, at the step S105, the GaN channel layer 140 is formed on the P-doping GaN layer 130. The GaN channel layer 140 is, for example, unintentionally doped GaN.

Then, at the step S106, the AlGaN barrier layer 150 is formed on the GaN channel layer 140.

Next, at the step S107, a dielectric layer 180 is formed on the AlGaN barrier layer 150. For example, the dielectric layer 180 could be formed via CVD process.

Then, at the step S108, the gate 160G, the source 160S and the drain 160D are form on the AlGaN barrier layer 150. A material of the gate 160G, the source 160S and the drain 160D comprises single metal material or multiple metal layers. The material of the gate 160G, the source 160S and the drain 160D is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof. In this step, the dielectric layer 180 could be patterned by lithography/etching process and then the gate 160G, the source 160S and the drain 160D could be formed by sputtering process.

Next, at the step S109, a plurality of contacts 190 are formed on the gate 160G, the source 160S and the drain 160D. The material of the contacts 190 is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof. In this step, the dielectric layer 180 could be deposited by CVD process, and the dielectric layer 180 could be patterned by lithography/etching process and then the contacts 190 could be formed by CVD process.

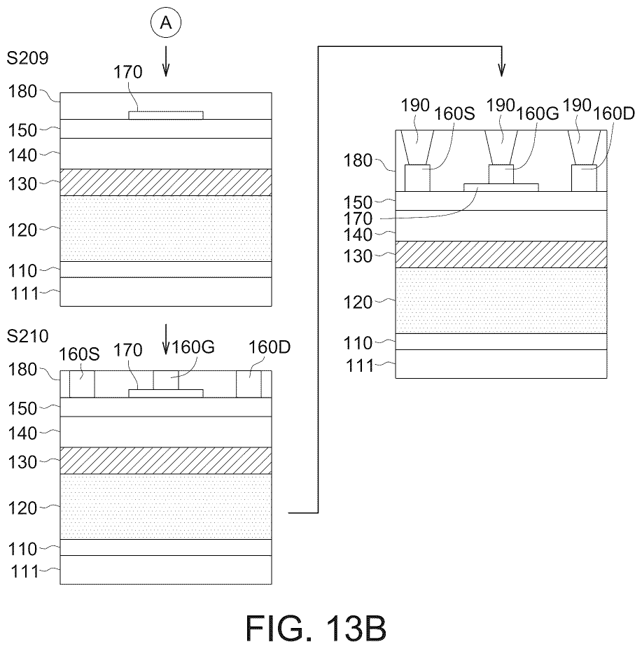

Please refer to FIGS. 13A and 13B, which show a flowchart of a manufacturing method of the E-mode HEMT 2000 including the semiconductor structure 100 according to one embodiment of the present disclosure. The manufacturing method of the E-mode HEMT 2000 includes steps S201 to S211.

At the step S201, the substrate 111 is provided. For example, the material of the substrate 111 could be silicon (e.g. Si (111), Si (110) . . . ), sapphire (Al2O3), SiC, GaN, AlN, SOI (silicon-on-insulator), SIS (semi-insulated silicon). The substrate 111 could be a P-type substrate.

Then, at the step S202, the nucleation layer 110 is formed on the substrate 111. The material of the nucleation layer 110 is, for example, AlN.

Next, at the step S203, the strain relief layer 120 is formed on the nucleation layer 110. The material of the strain relief layer 120 is, for example, AlGaN, GaN, AlN or the combination thereof. The strain relief layer 120 is doped P-type dopants, such as C, Fe, Mg, Mn, to have the modulated P-doping concentrations C1, C2, C3, . . . , Cx. The strain relief layer 120 could be formed via Metal-organic Chemical Vapor Deposition (MOCVD), Metal-organic Vapor-Phase Epitaxy (MOVPE), Organometallic Vapor-Phase Epitaxy (OMVPE), or Organometallic Chemical Vapor Deposition (OMCVD).

In one embodiment for the step S203 of forming the strain relief layer 120, pressure, growth rate, temperature or content of precursor is controlled to intrinsically dope the P-type dopants.

In another embodiment for the step S203 of forming the strain relief layer 120, a source with the P-type dopants is injected into chamber to extrinsically dope the P-type dopants. For example, carbon source may include CH4, C2H4, C3H8, C6H12, and/or CBr4; ion source may include Cp2Fe, and/or FeCl2; others p-doping source may include Mn and/or Mg. Those sources are controlled by source MFC flow.

In another embodiment for the step S203 of forming the strain relief layer 120, the P-type dopants are implanted into the strain relief layer. For example, P-type source for implanting includes Fe and/or Mg.

Then, at the step S204, the P-doping GaN layer 130 is formed on the strain relief layer 120. For example, the P-doping GaN layer 130 is a P-doping AlGaN layer and doped C or Fe.

Afterwards, at the step S205, the GaN channel layer 140 is formed on the P-doping GaN layer 130. The GaN channel layer 140 is, for example, unintentionally doped GaN.

Then, at the step S206, the AlGaN barrier layer 150 is formed on the GaN channel layer 140.

Afterwards, at the step S207, the p-GaN layer 170 is formed on the AlGaN barrier layer 150.

Then, at the step S208, the p-GaN layer 170 is patterned via lithography/etching process.

Next, at the step S209, the dielectric layer 180 is formed on the AlGaN barrier layer 150 and the p-GaN layer 170. For example, the dielectric layer 180 could be formed via CVD process.

Then, at the step S210, the source 160S and the drain 160D are form on the AlGaN barrier layer 150 and the gate 160G is formed on the p-GaN layer 170. A material of the gate 160G, the source 160S and the drain 160D comprises single metal material or multiple metal layers. The material of the gate 160G, the source 160S and the drain 160D is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof. In this step, the dielectric layer 180 could be patterned by lithography/etching process and then the gate 160G, the source 160S and the drain 160D could be formed by sputtering process.

Next, at the step S211, the contacts 190 are formed on the gate 160G, the source 160S and the drain 160D. The material of the contacts 190 is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof. In this step, the dielectric layer 180 could be deposited by CVD process, and the dielectric layer 180 could be patterned by lithography/etching process and then the contacts 190 could be formed by CVD process.

According to the embodiments described in this disclosure, a novel EPI structure with modulated doping buffer design is provided for robustness improvement on a semiconductor device, such as GaN HEMTs. For example, the modulated p-type doping buffer is used to increase HEMT device capacitance (create more junction as p-p^{-¿¿}, p-i or p-n) to achieve lower bulk leakage, high breakdown voltage (BV), and further minimized buffer trapping effect. In detail, additional multi-modulated C or Fe doping in the strain relief buffer layer is used to compensate nature n-type conductive buffer.

According to one example embodiment, a semiconductor structure is provided. The semiconductor structure includes a nucleation layer, a strain relief layer, a P-doping GaN layer, a GaN channel layer and an AlGaN barrier layer. The strain relief layer is disposed on the nucleation layer. The strain relief layer has a plurality of modulated P-doping concentrations. The P-doping GaN layer is disposed on the strain relief layer. The GaN channel layer is disposed on the P-doping GaN layer. The AlGaN barrier layer is disposed on the GaN channel layer.

Based on the semiconductor structure described in the previous embodiments, the modulated P-doping concentrations are staggered up and down.

Based on the semiconductor structure described in the previous embodiments, a ratio of two of the modulated P-doping concentrations is more than 2.

Based on the semiconductor structure described in the previous embodiments, one of the modulated P-doping concentrations is larger than two of the modulated P-doping concentrations.

Based on the semiconductor structure described in the previous embodiments, two of the modulated P-doping concentrations is larger than three of the modulated P-doping concentrations.

Based on the semiconductor structure described in the previous embodiments, two of the modulated P-doping concentrations is larger than one of the modulated P-doping concentrations.

Based on the semiconductor structure described in the previous embodiments, three of the modulated P-doping concentrations is larger than two of the modulated P-doping concentrations.

Based on the semiconductor structure described in the previous embodiments, two of the modulated P-doping concentrations is larger than three of the modulated P-doping concentrations.

Based on the semiconductor structure described in the previous embodiments, one of the modulated P-doping concentrations is larger than a default P-doping concentration of the P-doping GaN layer.

Based on the semiconductor structure described in the previous embodiments, the strain relief layer is doped C, Fe, Mg or Mn to have the modulated P-doping concentrations.

According to one example embodiment, a semiconductor structure is provided. The semiconductor structure includes a nucleation layer, a strain relief layer, a P-doping GaN layer, a GaN channel layer and an AlGaN barrier layer. The strain relief layer is disposed on the nucleation layer. The strain relief layer has more than one p-p^{-¿¿}, p-i, or p-n junctions. The P-doping GaN layer is disposed on the strain relief layer. The GaN chennel layer is disposed on the P-doping GaN layer. The AlGaN barrier layer is disposed on the GaN channel layer.

Based on the semiconductor structure described in the previous embodiments, the strain relief layer is doped C, Fe, Mg or Mn to have the more than one p-p^{-¿¿}, p-i, or p-n junctions.

According to one example embodiment, a manufacturing method of a semiconductor structure is provided. The manufacturing method of the semiconductor structure includes: forming a nucleation layer; forming a strain relief layer on the nucleation layer, wherein the strain relief layer is doped P-type dopants to have a plurality of modulated P-doping concentrations; forming a P-doping GaN layer on the strain relief layer; forming a GaN channel layer on the P-doping GaN layer; and forming an AlGaN barrier layer on the GaN channel layer.

Based on the manufacturing method of the semiconductor structure described in the previous embodiments, the step of forming the strain relief layer, pressure, growth rate, temperature or content of precursor is controlled to intrinsically dope the P-type dopants.

Based on the manufacturing method of the semiconductor structure described in the previous embodiments, the step of forming the strain relief layer, a source with the P-type dopants is injected into chamber to extrinsically dope the P-type dopants.

Based on the manufacturing method of the semiconductor structure described in the previous embodiments, the step of forming the strain relief layer, the P-type dopants are implanted into the strain relief layer.

Based on the manufacturing method of the semiconductor structure described in the previous embodiments, the strain relief layer is doped the P-type dopants to have more than one p-p^{-¿¿}, p-i, or p-n junctions.

Based on the manufacturing method of the semiconductor structure described in the previous embodiments, the modulated P-doping concentrations are staggered up and down.

Based on the manufacturing method of the semiconductor structure described in the previous embodiments, a ratio of two of the modulated P-doping concentrations is more than 2.

Based on the manufacturing method of the semiconductor structure described in the previous embodiments, one of the modulated P-doping concentrations is larger than two of the modulated P-doping concentrations.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a nucleation layer;
a strain relief layer, disposed on the nucleation layer, wherein the strain relief layer has a plurality of modulated P-doping concentrations;
a P-doping GaN layer, disposed on the strain relief layer;
a GaN channel layer, disposed on the P-doping GaN layer; and
an AlGaN barrier layer, disposed on the GaN channel layer.

2. The semiconductor structure according to claim 1, wherein the modulated P-doping concentrations are staggered up and down.

3. The semiconductor structure according to claim 1, wherein a ratio of two of the modulated P-doping concentrations is more than 2.

4. The semiconductor structure according to claim 1, wherein one of the modulated P-doping concentrations is higher than two of the modulated P-doping concentrations.

5. The semiconductor structure according to claim 1, wherein two of the modulated P-doping concentrations is larger than three of the modulated P-doping concentrations.

6. The semiconductor structure according to claim 1, wherein two of the modulated P-doping concentrations is higher than one of the modulated P-doping concentrations.

7. The semiconductor structure according to claim 1, wherein three of the modulated P-doping concentrations is higher than two of the modulated P-doping concentrations.

8. The semiconductor structure according to claim 1, wherein two of the modulated P-doping concentrations is higher than three of the modulated P-doping concentrations.

9. The semiconductor structure according to claim 1, wherein one of the modulated P-doping concentrations is higher than a default P-doping concentration of the P-doping GaN layer.

10. The semiconductor structure according to claim 1, wherein the strain relief layer is doped C, Fe, Mg or Mn to have the modulated P-doping concentrations.

11. A semiconductor structure, comprising:
a nucleation layer;
a strain relief layer, disposed on the nucleation layer, wherein the strain relief layer has more than one p-p^{-¿¿}, p-i, or p-n junctions;
a P-doping GaN layer, disposed on the strain relief layer;
a GaN channel layer, disposed on the P-doping GaN layer; and
an AlGaN barrier layer, disposed on the GaN channel layer.

12. The semiconductor structure according to claim 11, wherein the strain relief layer is doped C, Fe, Mg or Mn to have the more than one p-p^{-¿¿}, p-i, or p-n junctions.

13. A manufacturing method of a semiconductor structure, comprising:
forming a nucleation layer;
forming a strain relief layer on the nucleation layer, wherein the strain relief layer is doped P-type dopants to have a plurality of modulated P-doping concentrations;
forming a P-doping GaN layer on the strain relief layer;
forming a GaN channel layer on the P-doping GaN layer; and
forming an AlGaN barrier layer on the GaN channel layer.

14. The manufacturing method of the semiconductor structure according to claim 13, wherein the step of forming the strain relief layer, pressure, growth rate, temperature or content of precursor is controlled to intrinsically dope the P-type dopants.

15. The manufacturing method of the semiconductor structure according to claim 13, wherein the step of forming the strain relief layer, a source with the P-type dopants is injected into chamber to extrinsically dope the P-type dopants.

16. The manufacturing method of the semiconductor structure according to claim 13, wherein the step of forming the strain relief layer, the P-type dopants are implanted into the strain relief layer.

17. The manufacturing method of the semiconductor structure according to claim 13, wherein the strain relief layer is doped the P-type dopants to have more than one p-p^{-¿¿}, p-i, or p-n junctions.

18. The manufacturing method of the semiconductor structure according to claim 13, wherein the modulated P-doping concentrations are staggered up and down.

19. The manufacturing method of the semiconductor structure according to claim 13, wherein a ratio of two of the modulated P-doping concentrations is more than 2.

20. The manufacturing method of the semiconductor structure according to claim 13, wherein one of the modulated P-doping concentrations is larger than two of the modulated P-doping concentrations.
